(19) United States
(12) Patent Application Publication
(10) Pub. No.: US 2017/0069762 A1
(43) Pub. Date: Mar. 9, 2017

(54) MEMORY DEVICE AND METHOD FOR FABRICATING THE SAME

(71) Applicant: MACRONIX International Co., Ltd., Hsinchu (TW)

(72) Inventors: Jeng-Hwa Liao, Hsinchu (TW); Jung-Yu Shieh, Hsinchu (TW); Ling-Wuu Yang, Hsinchu (TW)

(21) Appl. No.: 14/845,828

(22) Filed: Sep. 4, 2015

(51) Int. Cl. H01L 29/788; H01L 29/66

(52) U.S. Cl. CPC H01L 29/7883; H01L 29/66825

(57) ABSTRACT

A memory device and a method for fabricating the same are provided. A memory device includes a tunneling dielectric layer located on a substrate. The floating gate includes a first doped portion on the tunneling dielectric layer and a second doped portion located on the first doped portion. The first doped portion includes a first dopant and a second dopant, and the second doped portion includes the first dopant. The grain size of the first doped portion is smaller than the grain size of the second doped portion, and the grain size of the first doped portion is between 150 Å to 200 Å. The memory device further includes an inter-gate dielectric layer on the floating gate and a control gate on the inter-gate dielectric layer. A source region and a drain region are located in the substrate besides sidewalls of the floating gate.

### BACKGROUND OF THE INVENTION

1. Technical Field

The invention relates to a semiconductor device and a method for fabricating the same.

2. Description of Related Art

Electronic products such as digital cameras, cameras in cell phones, and MP3 players have been growing rapidly in recent years, making the consumers' demands to storage media increase tremendously as well. Owing to the characteristics of non-volatility, low power consumption, smaller size, and non-mechanical structure, flash memory fits well as the storage media of these electronic products that are portable and powered by batteries.

However, in the trends of pursuing a higher integrity and a reduced size of integrated circuits, the area taken up by each of the memory cells in the flash memory needs to be reduced, and the line width of the device is reduced as well. Accordingly, a gate coupling ratio between a floating gate and a control gate decreases as well. Decrease in the gate coupling rate not only makes a threshold voltage (Vt) distribution in programming wider, but also reduces a memory window and a reliability (e.g., data storage and durability) of a memory device.

### SUMMARY OF THE INVENTION

The invention provides a memory device and a method for fabricating the same. In addition, the memory device may be formed to have improved data retention and endurance properties.

The invention provides a memory device, including a substrate, a control gate, a floating gate, a tunneling dielectric layer, an inter-gate dielectric layer, and a source region and a drain region. The tunneling dielectric layer is located on a substrate. The floating gate is located on the tunneling dielectric layer. The floating gate includes a first doped portion and a second doped portion on the first doped portion. The first doped portion includes a first dopant and a second dopant, and the second doped portion includes the first dopant. A grain size of the first doped portion is smaller than a grain size of the second doped portion, and a mean grain size of the first doped portion is in a range from 150 Å to 200 Å. The inter-gate dielectric layer is located on the floating gate. The control gate is located on the inter-gate dielectric layer. The source region and a drain region are located in the substrate beside sidewalls of the floating gate.

In the memory device according to an embodiment of the invention, materials of the first doped portion and the second doped portion include doped polysilicon.

In the memory device according to an embodiment of the invention, the first dopant includes arsenic, phosphorus or boron.

In the memory device according to an embodiment of the invention, the second dopant includes carbon, nitrogen, oxygen, or a combination thereof.

In the memory device according to an embodiment of the invention, a concentration of the first dopant in the first doped portion is lower than a concentration of the first dopant in the second doped portion.

In the memory device according to an embodiment of the invention, a conductivity of the first doped portion is lower than a conductivity of the second doped portion.

The invention provides a memory device, including a substrate, a control gate, a floating gate, a tunneling dielectric layer, an inter-gate dielectric layer, and a source region and a drain region. The tunneling dielectric layer is located on a substrate. The floating gate is located on the tunneling dielectric layer. The floating gate includes a first doped portion and a second doped portion on the first doped portion. The first doped portion includes a first dopant and a second dopant, and the second doped portion includes the first dopant. A conductivity of the first doped portion is lower than a conductivity of the second doped portion. The inter-gate dielectric layer is located on the floating gate. The control gate is located on the inter-gate dielectric layer. The source region and a drain region are located in the substrate beside sidewalls of the floating gate.

In the memory device according to an embodiment of the invention, materials of the first doped portion and the second doped portion include doped polysilicon.

In the memory device according to an embodiment of the invention, the first dopant includes arsenic, phosphorus or boron.

In the memory device according to an embodiment of the invention, the second dopant includes carbon, nitrogen, oxygen, or a combination thereof.

In the memory device according to an embodiment of the invention, a concentration of the first dopant in the first doped portion is lower than a concentration of the first dopant in the second doped portion.

In the memory device according to an embodiment of the invention, a mean grain size of the first doped portion is in a range from 150 Å to 200 Å.

The invention provides a method for fabricating a memory device. According to the method, a tunneling dielectric layer is formed on a substrate. Next, a first deposition process is performed by using a first gas mixture, so as to form a first doped portion of a floating gate on the tunneling dielectric layer. The first gas mixture includes a silicon source, a first dopant gas, and a second dopant gas. A second deposition process is performed by using a second gas mixture, so as to form a second doped portion of the floating gate on the first doped portion. The second gas mixture includes the silicon source and the first dopant gas. An inter-gate dielectric layer is formed on the second doped portion. Afterwards, a control gate is formed on the inter-gate dielectric layer. Subsequently, a source region and a drain region are formed in the substrate beside sidewalls of the floating gate. A conductivity type of the first doped portion and a conductivity type of the second doped portion are determined by the first dopant gas, and a grain size of the first doped portion is controlled by the second dopant gas.

In the method for fabricating the memory device according to an embodiment of the invention, the silicon source includes SiH₄, Si₂H₆, or a combination thereof.

In the method for fabricating the memory device according to an embodiment of the invention, the first dopant gas includes PH₃, AsH₃, or B₂H₆.

In the method for fabricating the memory device according to an embodiment of the invention, the second dopant gas includes C₂H₄, NH₃, O₃, or a combination thereof.

In the method for fabricating the memory device according to an embodiment of the invention, when the second dopant gas is C₂H₄, a flow rate of C₂H₄ is in a range from 1 sccm to 10 sccm.

In the method for fabricating the memory device according to an embodiment of the invention, a concentration of a first dopant of the first doped portion doped with the first dopant gas is lower than a concentration of the first dopant of the second doped portion doped with the first dopant gas.

In the method for fabricating the memory device according to an embodiment of the invention, a process temperature of the first deposition process and a process temperature of the second deposition process are in a range from 450° C. to 650° C.

In the method for fabricating the memory device according to an embodiment of the invention, a mean grain size of the first doped portion is in a range from 150 Å to 200 Å.

Based on above, in the process of forming the floating gate according to the embodiments of the invention, since the dopant gas including the dopant that prevents diffusion of silicon atoms is firstly introduced, the doped layer having a smaller grain size and a lower conductivity may be deposited on the tunneling dielectric layer, thereby allowing the memory device to achieve a narrower threshold voltage distribution curve, and consequently improving a reliability of the memory device. Thus, the memory device according to the embodiments of the invention has a high reliability in terms of data storage and endurance.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIGS. 1A to 1C are cross-sectional views illustrating a method for fabricating a memory device according to an embodiment of the invention.

FIG. 2 is a view illustrating a threshold voltage distribution in programming of a memory device.

### DESCRIPTION OF THE EMBODIMENTS

Reference will now be made in detail to the embodiments of the disclosure, examples of which are illustrated in the accompanying drawings. Wherever possible, the same reference numbers are used in the drawings and the description to refer to the same or like parts.

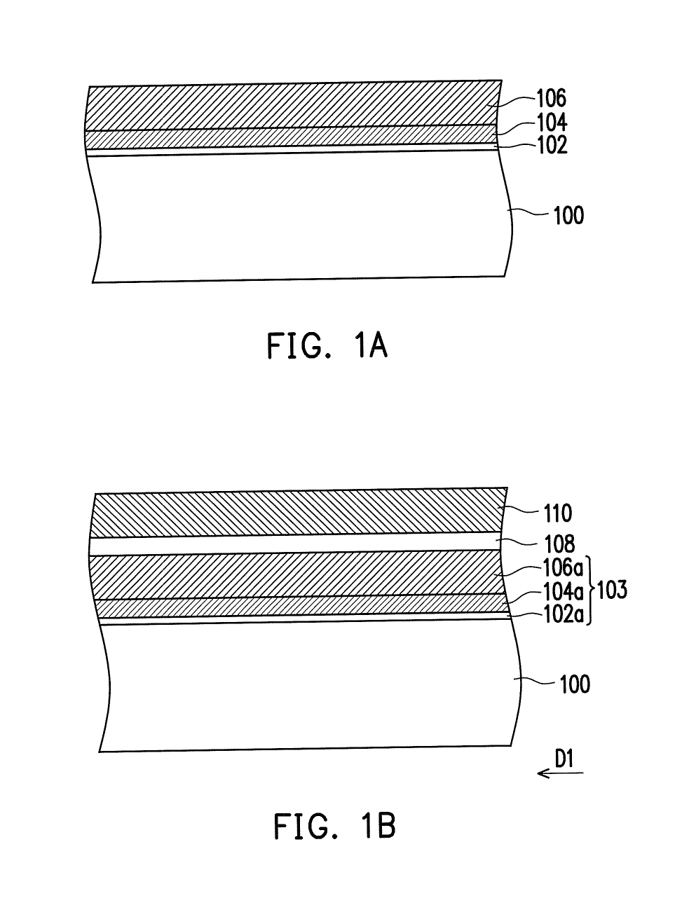

FIGS. 1A to 1C are cross-sectional views illustrating a method for fabricating a memory device according to an embodiment of the invention.

First of all, referring to FIG. 1A, a substrate 100 is provided. The substrate 100 is a semiconductor substrate, a semiconductor compound substrate, or a semiconductor over insulator (SOI) substrate, for example. The semiconductor includes atoms of Group IVA, such as silicon or germanium. The semiconductor compound includes a semiconductor compound formed of atoms of Group IVA, such as SiC or SiGe, or a semiconductor compound formed of atoms of Group IIIA and Group VA, such as GaAs.

Then, a tunneling dielectric material layer 102 is formed on the substrate 100. A material of the tunneling dielectric material layer 102 includes silicon oxide, silicon oxynitride, or a dielectric material having a dielectric constant higher than 4. A method of forming the tunneling dielectric material layer 102 includes performing a chemical vapor deposition process, an in-situ steam generation (ISSG) process, a low pressure radical oxidation process, or a furnace oxidation process, etc.

Then, a first deposition process is performed, so as to form a first doped layer 104 on the tunneling dielectric material layer 102. A material of the first doped layer 104 includes doped polysilicon, for example. The first deposition process is performed by performing a low pressure chemical vapor deposition process, for example, an operation pressure thereof is in a range from 50 Torr to 200 Torr, for example, and a process temperature thereof is in a range from 450° C. to 650° C., for example. A thickness of the first doped layer 104 is in a range from 100 Å to 300 Å, for example.

In this embodiment, a first gas mixture is introduced during the first deposition process. The first gas mixture includes a silicon source, a first dopant gas, and a second dopant gas, and the first doped layer 104 formed accordingly includes a first dopant provided by the first dopant gas and a second dopant provided by the second dopant gas. The silicon source includes SiH₄, Si₂H₆, or a combination thereof, for example. The first dopant gas is PH₃, AsH₃, or B₂H₆, for example. In this embodiment, a conductivity type of the first doped layer 104 may be determined by the first dopant gas. For example, when an N-type first doped region 104 is intended to form, the first dopant gas that is introduced is PH₃ or AsH₃, and when a P-type first doped region 104 is intended to form, the first dopant gas that is introduced is B₂H₆. The second dopant gas is C₂H₄, NH₃, O₃, or a combination thereof, for example. The first dopant includes arsenic, phosphorus or boron, for example. The second dopant includes carbon, nitrogen, oxygen, or a combination thereof, for example. The second dopant (e.g., carbon, nitrogen, oxygen, or a combination thereof) provided by the second gas mixture may prevent diffusion of silicon atoms during the first deposition process, so as to reduce expansion of a grain boundary. Thus, a grain size of the first doped layer 104 is smaller. In other words, the grain size of the first doped layer 104 may be controlled by adjusting a flow rate of the second dopant gas. A mean grain size of the first doped layer 104 is in a range from 150 Å to 200 Å, for example. In an embodiment, the first gas mixture is a gas mixture of SiH₄, PH₃, and C₂H₄. In addition, a flow rate of SiH₄ is in a range from 100 sccm to 250 sccm, a flow rate of PH₃ is in a range from 10 sccm to 200 sccm, and a flow rate of C₂H₄ is in a range from 1 sccm to 10 sccm.

Then, continuing to refer to FIG. 1A, a second deposition process is performed to form a second doped layer 106 on the first doped layer 104. In an embodiment, a material of the second doped layer 106 may be the same as the material of the first doped layer 104, such as doped polysilicon. The second doped layer 106 may also include the first dopant. However, a concentration of the first dopant in the second doped layer 106 is greater than a concentration of the first dopant in the first doped layer 104. A ratio between the concentration of the first dopant in the first doped layer 104 and the concentration of the first dopant in the second doped layer 106 is in a range from 1:6 to 1:2. In an embodiment, the ratio between the concentration of the first dopant in the first doped layer 104 and the concentration of the first dopant in the second doped layer 106 is approximately 1:3. In an embodiment, the second doped layer 106 does not include a second dopant. In another embodiment, the second doped layer 106 may also include the second dopant, but a concentration of the second dopant in the second doped layer 106 is lower than a concentration of the second dopant in the first doped layer 104. In other embodiments, a graded doped layer (not shown) may also be formed on the tunneling dielectric material layer 102 to replace the first doped layer 104 and the second doped layer 106. In addition, the concentration of the first dopant of the graded doped layer decreases in a direction from a top part of the graded doped layer toward the substrate 100, and the concentration of the second dopant of the graded doped layer increases in a direction from the top part of the graded doped layer toward the substrate 100.

The second deposition process is performed by performing a low pressure chemical vapor deposition process, for example. In the second deposition process, a second gas mixture is introduced. The second gas mixture includes the silicon source and the first dopant gas. An operation pressure of the second deposition process is in a range from 50 Torr to 200 Torr, for example, and a process temperature thereof is in a range from 450° C. to 650° C., for example. A thickness of the second doped layer 106 is in a range from 600 Å to 900 Å, for example.

When the second doped layer 106 is formed, no or only a small amount of the second dopant that prevents silicon diffusion is included, and the concentration of the first dopant in the second doped layer 106 is higher than the concentration of the first dopant in the first doped layer 104. Therefore, a grain size of the second doped layer 106 is greater than the grain size of the first doped layer 104. In an embodiment, the mean grain size of the first doped layer 104 is in a range from 150 Å to 200 Å, and a mean grain size of the second doped layer 106 is in a range from 300 Å to 500 Å, for example. In addition, since the grain size of the first doped layer 104 is smaller than the grain size of the second doped layer 106, and the concentration of the first dopant in the first doped layer 104 is lower than the concentration of the first dopant in the second doped layer 106, a conductivity of the first doped layer 104 is lower than a conductivity of the second doped layer 106.

Then, referring to FIGS. 1A and 1B, by performing a photolithography process and an etching process, the tunneling dielectric material layer 102, the first doped layer 104, and the second doped layer 106 are patterned, so as to form a plurality of strip-like stack structures 103 on the substrate 100. From bottom to top, each of the strip-like stack structures 103 sequentially includes a tunneling dielectric material layer 102a, a first doped layer 104a, and a second doped layer 106a. The strip-like stack structures 103 extend along a first direction D1, for example.

Then, an inter-gate dielectric material layer 108 and a conductive material layer 110 are sequentially formed on the substrate 100. In this embodiment, the inter-gate dielectric material layer 108 is a composite layer formed of an oxide-nitride-oxide (ONO) layer, for example. However, the invention is not limited thereto. The composite layer may include three or more layers. A method of forming the inter-gate dielectric material layer 108 includes performing a chemical vapor deposition process or a thermal oxidation process, etc. A material of the conductive material layer 110 includes doped polysilicon, for example. A method of forming the conductive material layer 110 includes performing a chemical vapor deposition process.

Then, referring to FIG. 1C, by performing a photolithography process and an etching process, the conductive material layer 110, the inter-gate dielectric material layer 108, and the strip-like stack structures 103 are patterned, so as to form a gate structure 112 on the substrate 100. From bottom to top, the gate structure 112 sequentially includes a tunneling dielectric layer 102b, a floating gate 105, an inter-gate dielectric layer 108a, and a control gate 110a. The floating gate 105 includes a first doped portion 104b and a second doped portion 106b. The control gate 110a and the inter-gate dielectric layer 108a extend along a second direction D2. The second direction D2 is different from the first direction D1, and the first direction D1 and the second direction D2 are perpendicular to each other, for example.

Then, using the gate structure 112 as an implantation mask, an ion implantation process is performed, so as to form a source region and a drain region 114 in the substrate 100 beside sidewalls of the gate structure 112. In this embodiment, the substrate 100 has a first conductivity type, and the source region and a drain region 114 has a second conductivity type. The first conductivity type is P type, for example, and the second conductivity type is N type, for example. Or, the first conductivity type is N type, and the second conductivity type is P type, for example. Accordingly, fabrication of the memory device of the invention is completed.

In the following, examples of the invention are provided to more specifically describe the invention. However, the materials and methods described in the following examples may be appropriately modified without departing from the spirit of the invention. Therefore, the scope of the invention shall not be defined and interpreted based on the specific examples described in the following.

### Example 1

In Example 1, a deposition process was performed by adopting a low pressure chemical vapor deposition process, so as to form a doped polysilicon layer on a silicon substrate. During the deposition process, a gas mixture including SiH₄, PH₃, and C₂H₄ was introduced. In addition, a flow rate of C₂H₄ is 4 sccm.

### Example 2

A method similar to the method of Example 1 was performed to form a doped polysilicon layer. A difference between Example 1 and Example 2 is that a flow rate of C₂H₄ in Example 2 is 7 sccm.

### Example 3

A method similar to the method of Example 1 was performed to form a doped polysilicon layer. A difference between Example 1 and Example 3 is that a flow rate of C₂H₄ in Example 3 is 10 sccm.

### Comparative Example

A method similar to the method of Example 1 was performed to form a doped polysilicon layer. A difference between Example 1 and Comparative Example is that a gas mixture that was introduced in Comparative Example only includes SiH₄ and PH₃.

Table 1 shows results concerning grain sizes of the doped polysilicon layers formed in Examples 1-3 and Comparative Example.

TABLE 1

| | P concentration | Flow rate of C₂H₄ | Mean grain |
|---|---|---|---|
| | (atom/cm³) | (sccm) | size (Å) |
| Example 1 | 1.4 × 10²⁰ | 4 | 182.4 |
| Example 2 | 1.4 × 10²⁰ | 7 | 175.3 |
| Example 3 | 1.4 × 10²⁰ | 10 | 152.1 |
| Comparative Example | 1.4 × 10²⁰ | 0 | 234.6 |

Based on the results of Table 1, under a circumstance that concentrations of phosphorous remain the same and a gas of C₂H₄ is introduced, the grain size of the doped polysilicon layer becomes smaller as the flow rate of the gas of C₂H₄ increases, because a dopant (i.e., carbon atoms) provided by the gas of C₂H₄ may prevent diffusion of silicon atoms during formation of the doped polysilicon layer, thereby reducing expansion of a grain boundary and consequently forming a doped polysilicon layer with a smaller grain size. Based on the results above, it can also be known that the grain size of the doped polysilicon layer may be controlled by adjusting the flow rate of the gas of C₂H₄.

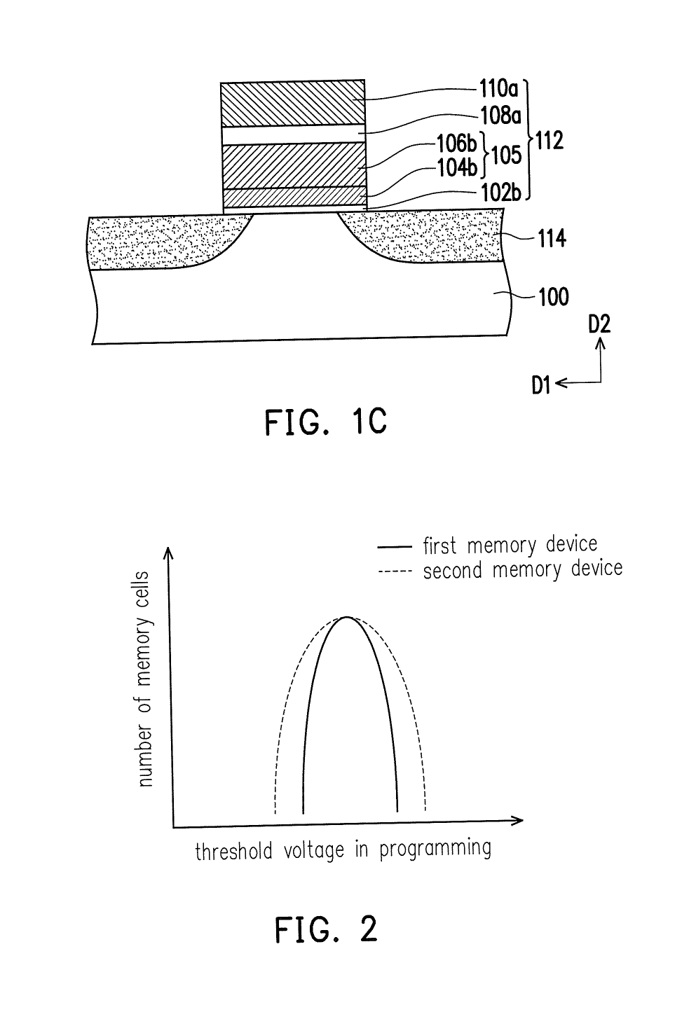

FIG. 2 is a view illustrating a threshold voltage distribution in programming of a memory device. A first memory device includes a floating gate formed by the first doped portion and the second doped portion of the invention, while a second memory device merely includes a floating gate doped with the first dopant. Based on FIG. 2, it can be seen that the first portion of the floating gate in the first memory device has a smaller grain size, the first memory device has a narrower threshold voltage distribution curve in programming. Thus, a reliability of the memory device is improved.

In view of the foregoing, in the invention, the dopant gas having the dopant that prevents diffusion of silicon atoms is introduced during the process of forming the floating gate, so as to deposit a doped layer having a smaller grain size on the tunneling dielectric layer. Then, another doped layer having a greater grain size is formed. The doped layer with a smaller grain size helps achieve a narrower threshold voltage distribution curve in programming, thereby improving the reliability of the memory device.

It will be apparent to those skilled in the art that various modifications and variations can be made to the structure of the disclosure without departing from the scope or spirit of the disclosure. In view of the foregoing, it is intended that the disclosure cover modifications and variations of the disclosure provided they fall within the scope of the following claims and their equivalents.

1. A memory device, comprising:
a tunneling dielectric layer, located on a substrate;
a floating gate comprising a first doped portion on the tunneling dielectric layer and a second doped portion on the first doped portion, wherein the first doped portion comprises a first dopant and a second dopant, and the second doped portion comprises the first dopant;
an inter-gate dielectric layer, located on the floating gate;
a control gate, located on the inter-gate dielectric layer; and
a source region and a drain region, located in the substrate beside sidewalls of the floating gate,
wherein the second dopant comprises oxygen,
wherein a grain size of the first doped portion is smaller than a grain size of the second doped portion.

2. The memory device as claimed in claim 1, wherein materials of the first doped portion and the second doped portion comprise doped polysilicon.

3. The memory device as claimed in claim 1, wherein the first dopant comprises arsenic, phosphorus or boron.

4. (canceled)

5. The memory device as claimed in claim 1, wherein a concentration of the first dopant in the first doped portion is lower than a concentration of the first dopant in the second doped portion.

6. The memory device as claimed in claim 1, wherein a conductivity of the first doped portion is lower than a conductivity of the second doped portion.

7. A memory device, comprising:
a tunneling dielectric layer, located on a substrate;
a floating gate, comprising a first doped portion on the tunneling dielectric layer and a second doped portion on the first doped portion, wherein the first doped portion comprises a first dopant and a second dopant, and the second doped portion comprises the first dopant;
an inter-gate dielectric layer, located on the floating gate;
a control gate, located on the inter-gate dielectric layer; and
a source region and a drain region, located in the substrate beside sidewalls of the floating gate,
wherein the second dopant comprises oxygen,
wherein a conductivity of the first doped portion is lower than a conductivity of the second doped portion.

8. The memory device as claimed in claim 7, wherein materials of the first doped portion and the second doped portion comprise doped polysilicon.

9. The memory device as claimed in claim 7, wherein the first dopant comprises arsenic, phosphorus or boron.

10. (canceled)

11. The memory device as claimed in claim 7, wherein a concentration of the first dopant in the first doped portion is lower than a concentration of the first dopant in the second doped portion.

12. The memory device as claimed in claim 7, wherein a mean grain size of the first doped portion is in a range from 150 Å to 200 Å.

13. A method for fabricating a memory device, comprising:
forming a tunneling dielectric layer on a substrate;
performing a first deposition process by using a first gas mixture, so as to form a first doped portion of a floating gate on the tunneling dielectric layer, wherein the first gas mixture comprises a silicon source, a first dopant gas, and a second dopant gas;
performing a second deposition process by using a second gas mixture, so as to form a second doped portion of the floating gate on the first doped portion, wherein the second gas mixture comprises the silicon source and the first dopant gas;
forming an inter-gate dielectric layer on the second doped portion;
forming a control gate on the inter-gate dielectric layer; and
forming a source region and a drain region in the substrate beside sidewalls of the floating gate,
wherein the second dopant gas comprises O₃,
wherein a conductivity type of the first doped portion and a conductivity type of the second doped portion are determined by the first dopant gas, and a grain size of the first doped portion is controlled by the second dopant gas.

14. The method for fabricating the memory device as claimed in claim 13, wherein the silicon source comprises SiH₄, Si₂H₆, or a combination thereof.

15. The method for fabricating the memory device as claimed in claim 13, wherein the first dopant gas comprises PH₃, AsH₃, or B₂H₆.

16-17. (canceled)

18. The method for fabricating the memory device as claimed in claim 13, wherein a concentration of a first dopant of the first doped portion doped with the first dopant gas is lower than a concentration of the first dopant of the second doped portion doped with the first dopant gas.

19. The method for fabricating the memory device as claimed in claim 13, wherein a process temperature of the first deposition process and a process temperature of the second deposition process are in a range from 450° C. to 650° C.

20. The method for fabricating the memory device as claimed in claim 13, wherein a mean grain size of the first doped portion is in a range from 150 Å to 200 Å.
